(19) United States
(12) Patent Application Publication
(10) Pub. No.: US 2019/0335593 A1
(43) Pub. Date: Oct. 31, 2019

(54) METHOD OF MANUFACTURING THE PRINTED CIRCUIT BOARD

(71) Applicant: Daeduck Electronics Co., Ltd., Gyeonggi-do (KR)

(72) Inventors: Dong-Hyun KIM, Gyeonggi-do (KR); Min-Seok LEE, Gyeonggi-do (KR); Jun-Koo KWON, Gyeonggi-do (KR); Dae-Geun KANG, Incheon (KR)

(21) Appl. No.: 16/177,717

(22) Filed: Nov. 1, 2018

(30) Foreign Application Priority Data
Apr. 26, 2018 (KR) 2018-0048250
Jun. 14, 2018 (KR) 2018-0067883

(51) Int. Cl. H05K 3/46; H05K 3/42; H05K 3/10

(52) U.S. Cl. CPC H05K 3/4644; H05K 3/107; H05K 3/429

(57) ABSTRACT

The present invention discloses a method of making a printed circuit board comprising the steps of forming a sublayer comprising a combination of alternating copper and insulating layers, which has a first through-hole the internal wall of which is copper electroplated, forming a sublayer attaching structure comprising a hardened (cured) epoxy layer and adhesive films on top of both surfaces of said epoxy layer, which has q second through-hole filled with conducting ink, and (c) laying the sublayer attaching structure in contact between the upper sublayer and lower sublayer in such a way that said first through-hole is aligned with said second through-hole, and performing a complete hardening (curing) process.

### CROSS REFERENCE TO RELATED APPLICATION

This application claims priority under 35 USC § 119 to Korean Patent Applications No. 10-2018-0067883 (Filing Date: Jun. 14, 2018) and No. 10-2018-0048250 (Filing Date: Apr. 26, 2018), the contents of which are incorporated herein by reference in their entirety. The list of the prior art is the following: Korean Patent Publication No. 10-2014-0005064, US Patent Publication No. 2003/0121699 A1, and European Patent Publication EP 0 651 602 B1.

### FIELD OF THE INVENTION

The present invention relates to a method of manufacturing a printed circuit board (PCB) and more particularly a method of fabricating a thick, for instance thicker than 8T, multi-layered circuit board having holes with a high aspect ratio, for example greater than 36:1.

### BACKGROUND OF THE INVENTION

FIGS. 1a, 1b, 1c, 1d are schematic diagrams illustrating a typical press lamination process for making a multi-layered PCB. Referring to FIGS. 1a and 1b, we see that the press lamination is performed by laying the PREPREG (PPG, 20) between two sublayers (Board A, 10; and Board B, 30) and pressing the stacked layers. Here, the sublayer can be a multi-layered circuit board. The PREPREG (20) which is inserted like a sandwich between the two sublayers can be an uncured (not hardened) EPOXY.

Through-holes (40) are fabricated by drilling process and the copper electroplating is performed on the surface of the internal wall of the through-holes, thereby each copper layer of the sublayer is electrically connected together. Referring to FIG. 1d, we see that solder resist (50) is printed on the surface of the substrate.

Recently, the thickness of the circuit board gets thicker (even thicker than 8T) as the minimum feature size of the circuit shrinks. Furthermore, the aspect ratio gets greater than 36:1 and even larger number of sublayers is stacked in the circuit board due to the requirement of fine pattern generation. If, however, the aspect ratio increases it will be even more difficult to fill out the hole by copper electroplating. Furthermore, the drilling process becomes even more challenging if the thickness of the circuit board gets thicker.

### SUMMARY OF THE INVENTION

Accordingly, the goal of the present invention is to provide a method of fabricating a relatively thick circuit board having holes with high aspect ratio.

The present invention has a feature in that the traditional press lamination process is not employed. Instead of employing the conventional PREPREG, the present invention employs a CCL (copper-cladded laminate) layer, an adhesive film and a conducting ink.

The present invention has a unique feature in that the high-temperature and high-pressure press process (lamination process) is not employed. No PREPREG is employed for attaching the sublayers, either. The present invention employs its own sublayer attaching structure.

According to the present invention, a sublayer attaching structure is formed by attaching an adhesive film and a carrier on both surfaces of the hardened (cured) epoxy. The hardened epoxy can be easily obtained by removing the copper layer from the CCL. The structure is then cured (a first curing process), and holes are made via drilling process. The holes are then filled out with conducting ink to form a copper plug. Thereafter, a second curing process is performed for hardening the conducting ink. Finally, we peel off the carrier and thereby the surface of the adhesive film is exposed. Now the structure comprises the exposed surface of the adhesive film on top of the epoxy having the holes filled with hardened ink for electrical conduction, which is now called a sublayer attaching structure.

Now we can stack the upper sublayer and the lower sublayer by inserting the sublayer attaching structure in between those two sublayers in accordance with the present invention wherein the adhesive film attaches the sublayer and the conducting ink plugged in the holes is in electrical contact with the copper electroplated layer of the holes of the sublayer.

### BRIEF DESCRIPTION OF THE DRAWINGS

FIGS. 1a, 1b, 1c, and 1d are schematic diagrams illustrating the conventional press lamination process for fabricating the printed circuit board.

FIGS. 2a, 2b and 2c are schematic diagrams which illustrate the fabricating the printed circuit board by employing the sublayer attaching structure in accordance with a first preferred embodiment of the present invention.

FIGS. 3a, 3b and 3c are schematic diagrams which illustrate the fabricating the sublayer attaching structure in accordance with a first preferred embodiment of the present invention.

FIGS. 4a, 4b and 4c are schematic diagrams which illustrate the fabricating the printed circuit board by employing the sublayer attaching structure in accordance with a second preferred embodiment of the present invention.

FIG. 5 is a schematic diagram which illustrates the cross-sectional view of the substrate which has been fabricated by employing the sublayer attaching structure in accordance with a second preferred embodiment of the present invention.

FIGS. 6a, 6b and 6c are schematic diagrams which illustrate the fabricating the printed circuit board by employing the sublayer attaching structure in accordance with a third preferred embodiment of the present invention.

FIG. 7 is a schematic diagram which illustrates the cross-sectional view of the substrate which has been fabricated by employing the sublayer attaching structure in accordance with a third preferred embodiment of the present invention.

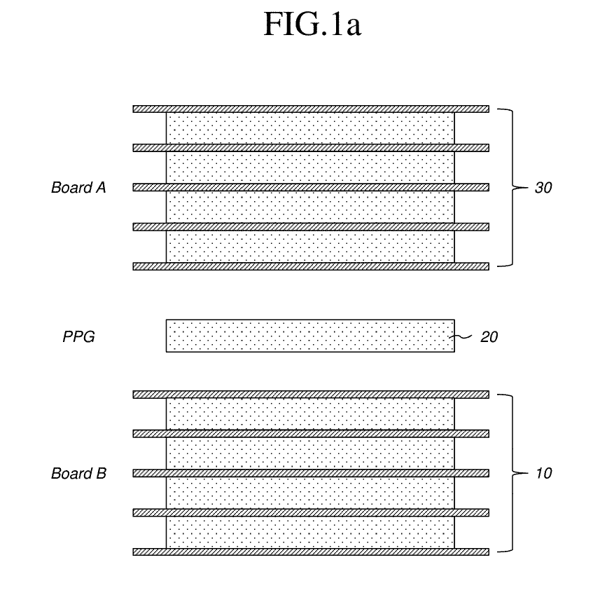

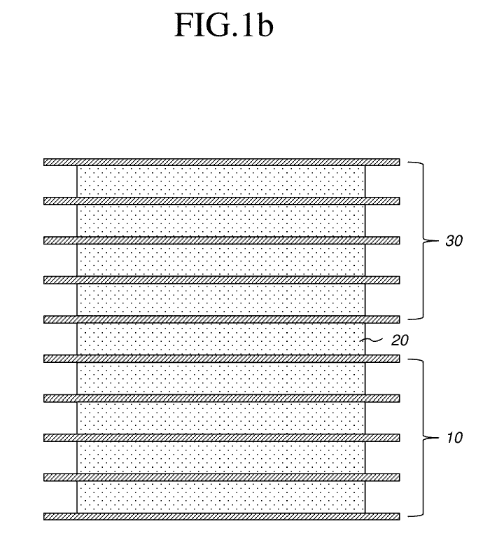

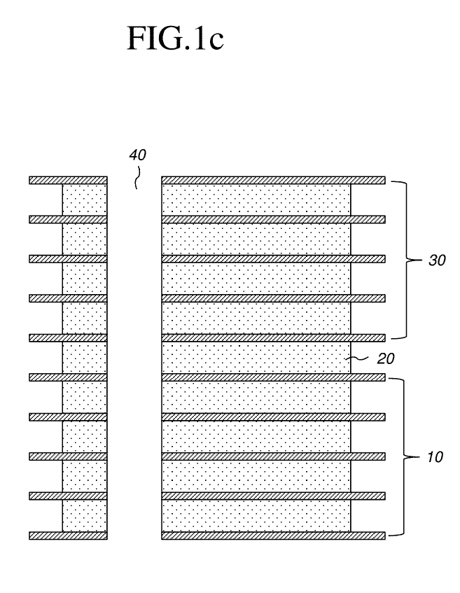

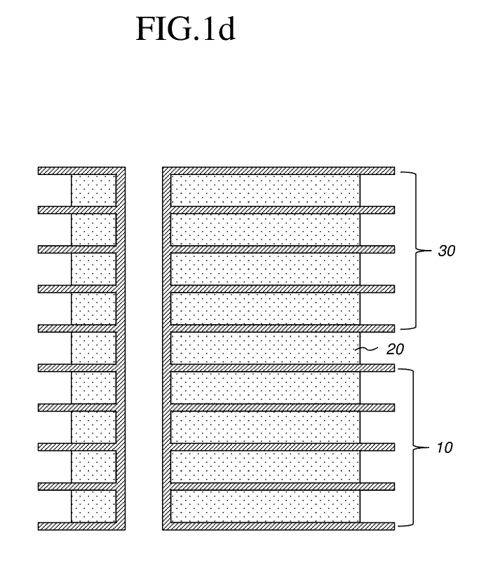

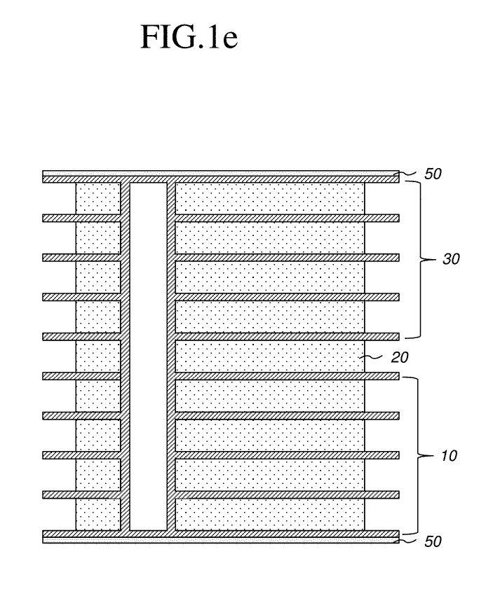

### DETAILED DESCRIPTION OF THE INVENTION

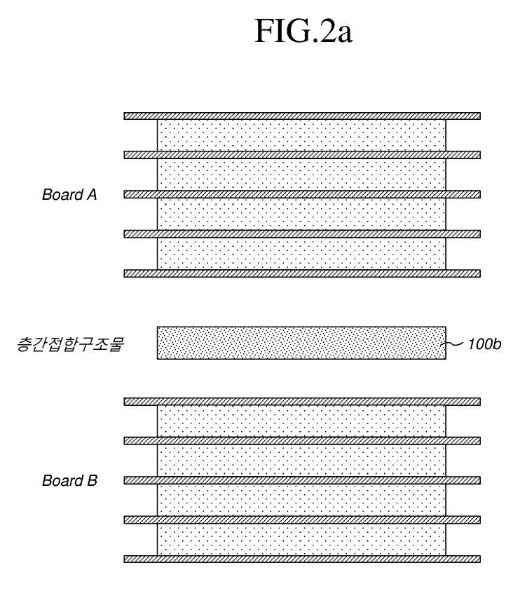

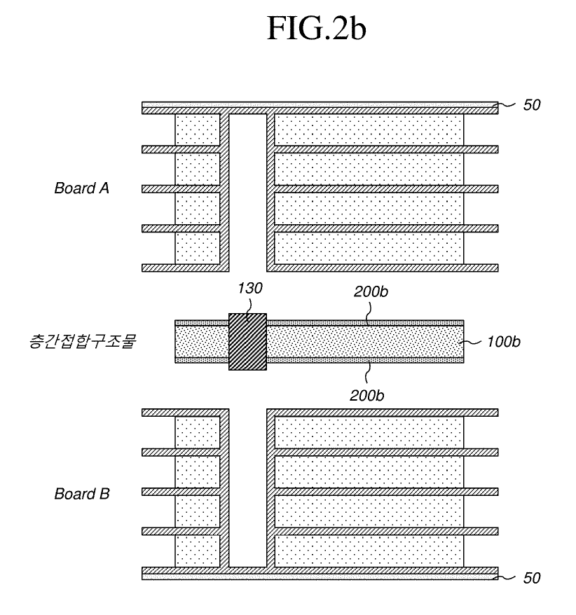

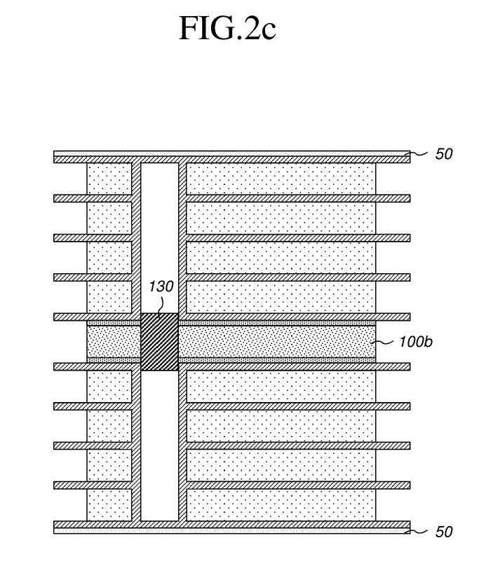

Detailed descriptions will be made on preferred embodiments and constitutional features of the fabricating method in accordance with the present invention with reference to attached figures from FIGS. 2 to 7.

The present invention has a unique feature in that the high-temperature and high-pressure press process (lamination process) is not employed. The present invention has a feature in that the adhesive film and conducting ink are employed. Furthermore, the conventional technique utilizes the uncured epoxy resin, PREPREG. In the meanwhile, this invention employs the cured epoxy, namely hardened epoxy.

The present invention discloses a method of making a printed circuit board comprising the steps of forming a sublayer comprising a combination of alternating copper and insulating layers, which has a first through-hole the internal wall of which is copper electroplated, forming a sublayer attaching structure comprising a hardened (cured) epoxy layer and adhesive films on top of both surfaces of said epoxy layer, which has a second through-hole filled with conducting ink, and (c) laying the sublayer attaching structure in contact between the upper sublayer and lower sublayer in such a way that said first through-hole is aligned with said second through-hole, and performing a complete hardening (curing) process.

FIGS. 2a, 2b and 2c are schematic diagrams which illustrate the fabricating the printed circuit board by employing the sublayer attaching structure in accordance with a first preferred embodiment of the present invention.

FIG. 2a illustrates a technique for stacking two sublayers by sandwiching a sublayer attaching structure in accordance with the present invention as a basic embodiment. It is also possible to stack a multiple number of sublayers in accordance with the present invention.

Referring to FIG. 2a, each sublayer (Board A and Board B) comprises a combination of several layers of copper layer and insulating layer. The sublayer also has a hole for electrical connection between the layers. Referring FIGS. 2b and 2c, the sublayer attaching structure unites the upper sublayer with the lower sublayer.

The sublayer attaching structure in accordance with the present invention comprises an adhesive film (200) coated on top of the cured epoxy (100b). The adhesive film (200b) works for uniting the upper sublayer with the lower sublayer. The hardened epoxy (100b) has holes which are aligned with the holes of the sublayer for electrical connection. The inside of the holes of the sublayer attaching structure is plugged with the conducting ink which is also hardened. When the sublayer is stacked via the sublayer attaching structure, the conducting ink (130) which is plugged in the hole electrically connects the copper-electroplated layer on the wall of the holes of the sublayer.

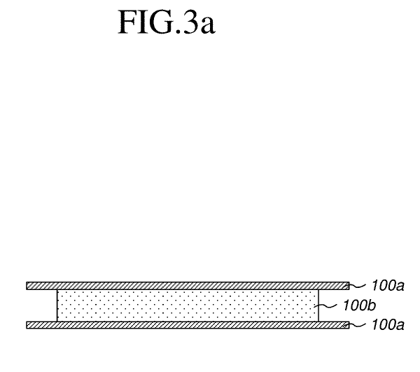

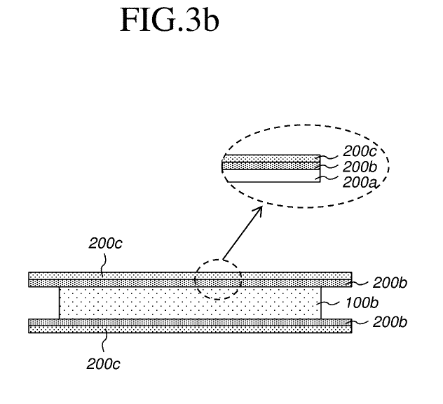

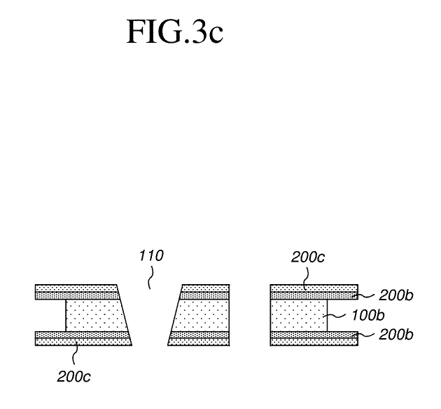

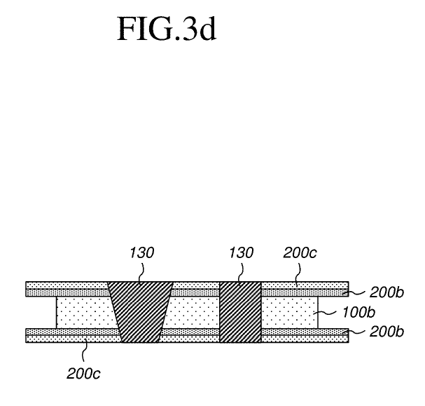

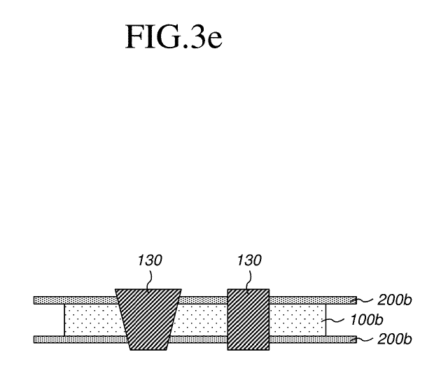

FIGS. 3a, 3b and 3c are schematic diagrams which illustrate the fabricating the sublayer attaching structure in accordance with a first preferred embodiment of the present invention.

Referring to FIG. 3a, each copper layer (100a, 100c) on both top and bottom surfaces of CCL is removed and we have a cured epoxy, namely hardened epoxy (100b). Referring to FIG. 3b, an adhesive film is coated on each side of the hardened epoxy (100b).

Here, the adhesive layer comprises a base film (200a), adhesive film (200b), and carrier tape (200c). Referring FIG. 3b, when we attach the adhesive layer on the surface of the epoxy (100b), we peel off the base film (200c) and attach the adhesive film (200b) and carrier tape (200a). Thereafter, a curing process follows (a first curing process). As a preferred embodiment of a first curing process, the roll lamination at 50˜150° C. can be utilized for inducing the partial hardening.

Referring to FIG. 3c, either laser drill or CNC drill can be used for making holes (110). Referring to FIG. 3d, the inside of the holes is filled with conducting ink (130) by printing, followed by a second curing process.). As a preferred embodiment of a second curing process, oven baking at 80˜180° C. for two hours can be utilized.

Here, the carrier tape (200c) works as a protector for the adhesive film (200b) during the physical process such as the laser drill or the CNC drill process. It should be noted that the carrier tape should not be peeled off from the adhesive film during the chemical process like plasma cleaning and desmear process. The adhesive film in accordance with the present invention can be hardened (cured) in a stepped manner. The adhesive film should be cured not during the first curing process but during the final stage.

Referring to FIG. 3e, we now expose the surface of the adhesive film (200b) and the conducting ink (130) which is plugged in the hole (100) by removing the carrier tape (200c).

As aforementioned in FIG. 2b, the upper sublayer and the lower sublayer is now united by inserting the sublayer attaching structure therein between those two sublayers. As a preferred embodiment in accordance with the present invention, we can perform a third curing process by oven baking at 150˜250° C. for less than 4 hours. As an alternative embodiment in accordance with the present invention, we can employ high-temperature high-press press lamination process.

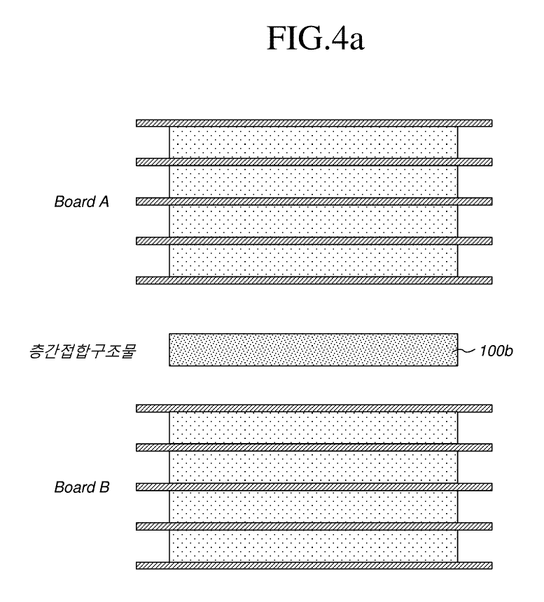

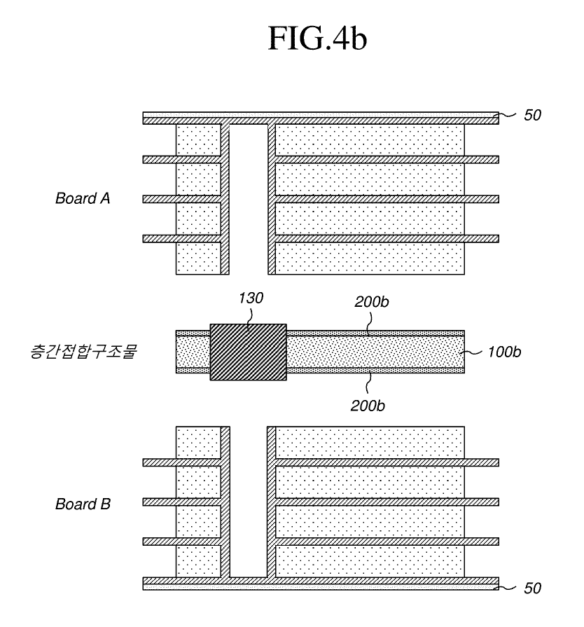

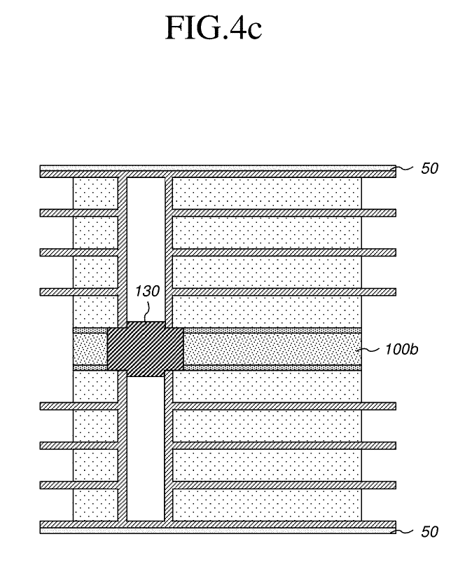

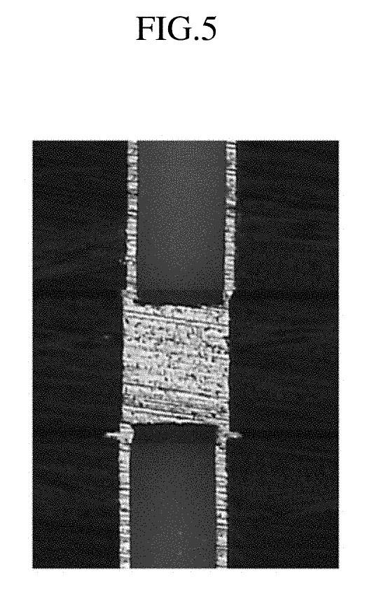

FIGS. 4a, 4b and 4c are schematic diagrams which illustrate the fabricating the printed circuit board by employing the sublayer attaching structure in accordance with a second preferred embodiment of the present invention. The second embodiment in accordance with the present invention has a feature in a sense that all the copper layer on the surface (copper pad) is eliminated before the sublayer attaching structure is interlaid between two sublayers. In addition, the second embodiment has a feature in that the diameter of the holes of the sublayer attaching structure is greater than that of the sublayer. Referring FIGS. 4b and 4c, we should note that the electroplated copper layer is nailed into the hardened conducting ink which is plugged in the holes, which makes those two materials electrically conductive. FIG. 5 is a schematic diagram which illustrates the cross-sectional view of the substrate which has been fabricated by employing the sublayer attaching structure in accordance with a second preferred embodiment of the present invention.

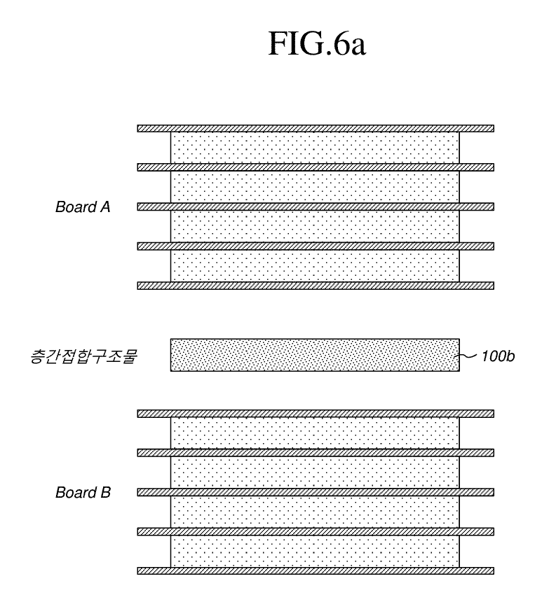

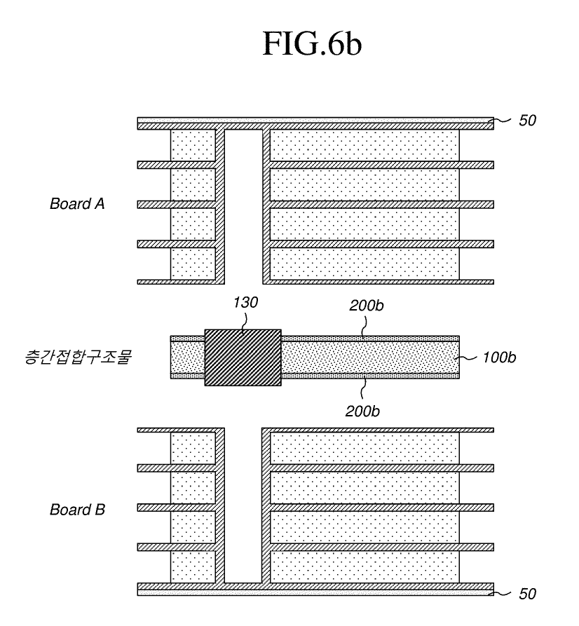

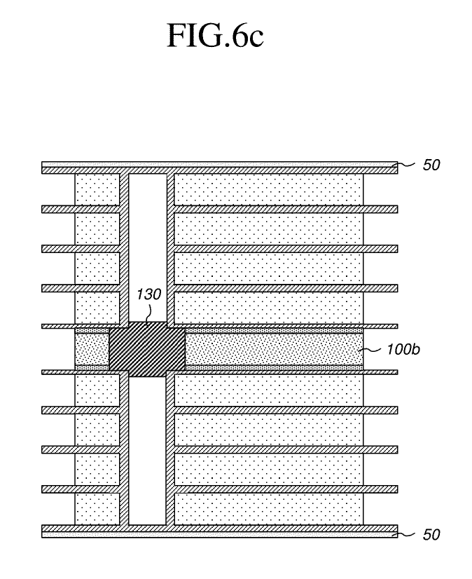

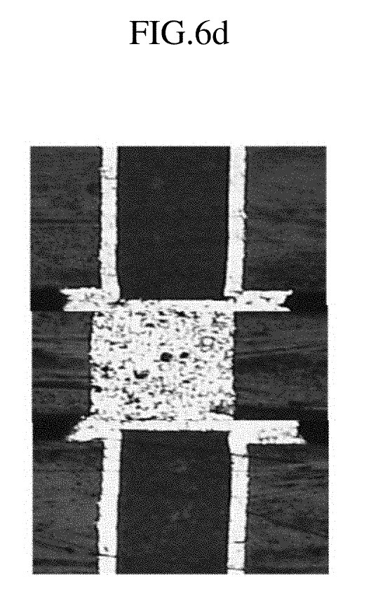

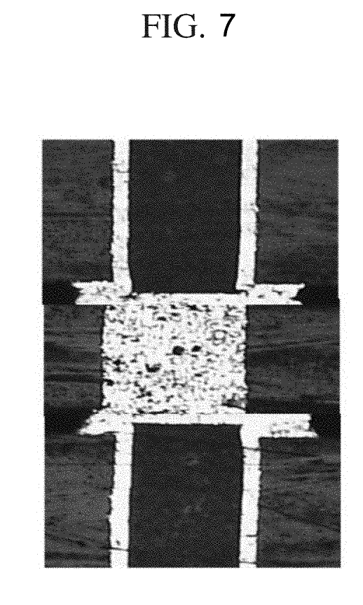

FIGS. 6a, 6b and 6c are schematic diagrams which illustrate the fabricating the printed circuit board by employing the sublayer attaching structure in accordance with a third preferred embodiment of the present invention. The third embodiment in accordance with the present invention has a feature in a sense that the copper layer on the surface (copper pad) is partially eliminated before the sublayer attaching structure is interlaid between two sublayers. Furthermore, the third embodiment has a feature in that the diameter of the holes of the sublayer attaching structure is greater than that of the sublayer. Referring FIGS. 6b and 6c, we should note that the internal wall of the hole which is copper electroplated, is in contact with the hardened conducting ink which is plugged in the holes, which makes those two materials electrically conductive. FIG. 7 is a schematic diagram which illustrates the cross-sectional view of the substrate which has been fabricated by employing the sublayer attaching structure in accordance with a third preferred embodiment of the present invention.

The present invention can be applied to board to board connection after the fabrication of the circuit board. We can adjust the thickness of the circuit board as we wish. We can reduce the aspect ratio of the holes by employing this technology by more than 50 percent. The present invention can respond to the variation of the scales since the hardened epoxy is utilized. It is also possible to reduce the thickness of the board by employing the laser via holes instead of direct through holes.

The aforementioned somewhat widely improves the characteristics and technical advantages of the present invention so that the scope of the invention to be described later can be more clearly understood. The additional characteristics and technical advantages that constitute the scope of the present invention will be described below. The features that the disclosed concept and specific embodiments of the present invention can be instantly used as a basis designing or correcting other structure for accomplishing a similar object with the present invention should be recognized by those skilled in the art.

Further, it will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A fabricating method of the Printed Circuit Board, comprising the steps of:
(a) forming a sublayer comprising a combination of alternating copper and insulating layers, which has a first through-hole the internal wall of which is copper electroplated;
(b) forming a sublayer attaching structure comprising a hardened (cured) epoxy layer and adhesive films on top of both surfaces of said epoxy layer, which has q second through-hole filled with conducting ink; and
(c) laying the sublayer attaching structure in contact between the upper sublayer and lower sublayer in such a way that said first through-hole is aligned with said second through-hole, and performing a complete hardening (curing) process.

2. The method as set forth in claim 1, characterized in that the step (b) further comprises the steps of:
(b1) laying an adhesive film and then a carrier tape on both sides of the hardened (cured) epoxy and performing a first curing process in such a way that said adhesive film is not completely but partially cured;
(b2) forming a second through-hole by drilling process;
(b3) filling out said second through-hole with a conducting ink and performing a second curing process for making a hole plug by hardening said conducting ink, however, in such a way that said adhesive film is not completely hardened (cured); and
(b4) exposing the surface of the hole plug and the surface of the adhesive film by removing the carrier tape.

3. The method as set forth in claim 2, characterized in that the hardened (cured) epoxy of the step (b1) is prepared by removing the copper layer on both sides of the CCL.

4. The method as set forth in claim 2, characterized in that said first curing process of the step (b1) is a roll lamination process at 50˜150° C.

5. The method as set forth in claim 2, characterized in that said second curing process of the step (b3) is an oven baking process at 80˜180° C. for less than 2 hours.

6. The method as set forth in claim 2, characterized in that said step of laying an adhesive film and then a carrier tape on both sides of the hardened (cured) epoxy is utilizing a structure comprising a base film, an adhesive film, and a carrier tape and then removing the base film.

7. The method as set forth in claim 1, characterized in that said complete curing process of the step (c) is an oven baking process at 150˜250° C. for less than 4 hours.

8. The method as set forth in claim 1, characterized in that said complete curing process of the step (c) is a high-temperature high-pressure press (lamination) process.

9. The method as set forth in claim 1, characterized in that said diameter of said second through-hole is greater than that of said first through-hole.

10. The method as set forth in claim 1, characterized in that the copper pad on top of said first through-hole which will be in contact with the sublayer should be either partially or completely eliminated before stacking.
